(19) United States
(12) Patent Application Publication
(10) Pub. No.: US 2026/0182064 A1
(43) Pub. Date: Jun. 25, 2026

(54) IMAGE SENSOR AND METHOD OF FABRICATING THE SAME

(71) Applicant: Samsung Electronics Co., Ltd., Suwon-si (KR)

(72) Inventors: Jong Uk Kim, Suwon-si (KR); Taemin Kim, Suwon-si (KR); Hyo Eun Kim, Suwon-si (KR); Sangjin Choi, Suwon-si (KR)

(73) Assignee: Samsung Electronics Co., Ltd., Suwon-si (KR)

(21) Appl. No.: 19/389,835

(22) Filed: Nov. 14, 2025

(30) Foreign Application Priority Data
Dec. 23, 2024 (KR) 10-2024-0194339

(51) Int. Cl. H10F 39/00; H10F 39/12; H10F 39/18

(52) U.S. Cl. CPC H10F 39/807; H10F 39/014; H10F 39/182; H10F 39/199; H10F 39/8063

(57) ABSTRACT

An image sensor and a method of fabricating the same are disclosed. The image sensor may include a plurality of light-receiving regions formed on a first surface of a substrate and disposed adjacent to each other, the plurality of light-receiving regions including a first light-receiving region and a second light-receiving region disposed adjacent to the first light-receiving region; a photodiode isolation pattern formed on the first surface of the substrate, the photodiode isolation pattern configured to electrically isolate the first light-receiving region from the second light-receiving region; and a back-side structure disposed on a second surface of the substrate opposite from the first surface, the back-side structure comprising a grid air region and a light-scattering air region, wherein the grid air region has a grid shape, and wherein the light-scattering air region overlaps with the first light-receiving region.

### CROSS-REFERENCE TO RELATED APPLICATION

This application claims priority from Korean Patent Application No. 10-2024-0194339, filed on Dec. 23, 2024, in the Korean Intellectual Property Office, and all the benefits accruing therefrom under 35 U.S.C. § 119, the entire contents of which are hereby incorporated by reference.

### TECHNICAL FIELD

Apparatuses and methods consistent with some embodiments of the present disclosure relate to an image sensor and methods of making the same, and more particularly, to an image sensor configured to realize a clear image quality.

### BACKGROUND

An image sensor is a semiconductor device converting an optical image to electric signals. Image sensors are classified into two types: a charge coupled device (CCD) type and a complementary metal-oxide-semiconductor (CMOS) type. The CMOS-type image sensor is commonly referred to as a CIS. The CIS includes a plurality of pixels that are two-dimensionally arranged. Each of the pixels may include a photodiode (PD), which is used to convert incident light to an electric signal.

### SUMMARY

Some embodiments of this disclosure provide an image sensor configured to realize a clear image quality.

Some embodiments of this disclosure provide a method of fabricating an image sensor.

In some embodiments of this present disclosure, an image sensor may include a plurality of light-receiving regions formed on a first surface of a substrate and disposed adjacent to each other, the plurality of light-receiving regions including a first light-receiving region and a second light-receiving region disposed adjacent to the first light-receiving region. The sensor may further include a photodiode isolation pattern formed on the first surface of the substrate, the photodiode isolation pattern configured to electrically isolate the first light-receiving region from the second light-receiving region, and a back-side structure disposed on a second surface of the substrate opposite from the first surface, the back-side structure comprising a grid air region and a light-scattering air region, wherein the grid air region has a grid shape, and wherein the light-scattering air region overlaps with the first light-receiving region.

In some embodiments of this present disclosure, an image sensor may include a plurality of light-receiving regions formed on a substrate, and a back-side structure disposed on a rear surface of the substrate, the back-side structure comprising a grid air region and a light-scattering air region. The grid air region has a grid shape, and the light-scattering air region overlaps with a light-receiving region of the plurality of light-receiving regions, and wherein a refractive index of a material constituting the back-side structure is higher than a refractive index of the grid air region or the light-scattering air region.

In some embodiments of this present disclosure, an image sensor may include a plurality of light-receiving regions formed on a first surface of a substrate and including a first light-receiving region and a second light-receiving region disposed adjacent to the first light-receiving region, a photodiode isolation pattern configured to electrically isolate the first light-receiving region from the second light-receiving region, a photodiode disposed in each of the plurality of light-receiving regions of the substrate, a transfer transistor disposed on the first surface of the substrate, a floating diffusion region disposed on a portion of the substrate adjacent to the transfer transistor, a fixed charge layer covering a second surface of the substrate, and a back-side structure formed on the fixed charge layer. The back-side structure comprises a light-transparent pattern comprising a grid air region and a light-scattering air region, and a micro lens layer disposed on the light-transparent pattern, wherein the grid air region has a grid shape, wherein the light-scattering air region overlaps with the first light-receiving region, and wherein a refractive index of the light-transparent pattern is higher than a refractive index of the grid air region or the light-scattering air region.

In some embodiments of this present disclosure, a method of fabricating an image sensor may include forming a light-transparent layer on a rear surface of a substrate, the substrate comprising a plurality of light-receiving regions, etching the light-transparent layer to form a light-transparent pattern, forming a micro lens layer on the light-transparent pattern, and etching the micro lens layer to form a plurality of micro lenses. The light-transparent pattern overlaps with the plurality of light-receiving regions, wherein the light-transparent pattern comprises a grid air region and a light-scattering air region, and wherein the light-transparent pattern comprises at least one light-scattering air region spaced apart from the grid air region.

### BRIEF DESCRIPTION OF THE FIGURES

The accompanying drawings are included to provide a further understanding of disclosed example embodiments, and are incorporated in and constitute a part of this specification. In the drawings:

FIG. 1 is a plan view illustrating an image sensor, consistent with some embodiments of the present disclosure.

FIG. 2A is a sectional view along a line A-A′ of FIG. 1, consistent with some embodiments of the present disclosure.

FIG. 2B is a sectional view along a line B-B′ of FIG. 1, consistent with some embodiments of the present disclosure.

FIG. 2C is a diagram illustrating a propagation path of light that is incident into the image sensor of FIG. 2A, consistent with some embodiments of the present disclosure.

FIGS. 3A to 3D are sectional views sequentially illustrating a process of fabricating an image sensor with the section of FIG. 2A, consistent with some embodiments of the present disclosure.

FIGS. 4A to 4D are sectional views illustrating exemplary image sensors, consistent with some embodiments of the present disclosure.

FIGS. 5A and 5B are plan views illustrating exemplary image sensors, consistent with some embodiments of the present disclosure.

FIG. 6 is a plan view illustrating an exemplary image sensor, consistent with some embodiments of the present disclosure.

FIG. 7 is a sectional view along a line A-A′ of FIG. 6, consistent with some embodiments of the present disclosure.

FIG. 8 is a plan view illustrating an image sensor, consistent with some embodiments of the present disclosure.

FIG. 9 is a sectional view along a line C-C′ of FIG. 8, consistent with some embodiments of the present disclosure.

FIG. 10 is a sectional view illustrating an exemplary image sensor, consistent with some embodiments of the present disclosure.

FIG. 11 is a sectional view illustrating an image sensor, consistent with some embodiments of the present disclosure.

FIG. 12 is a sectional view illustrating an image sensor, consistent with some embodiments of the present disclosure.

FIG. 13 is a sectional view illustrating an image sensor, consistent with some embodiments of the present disclosure.

### DETAILED DESCRIPTION

Example embodiments of the present disclosure will now be described more fully with reference to the accompanying drawings, in which exemplary embodiments are shown. Like reference numerals in the drawings denote like elements, and therefore, their description will be omitted.

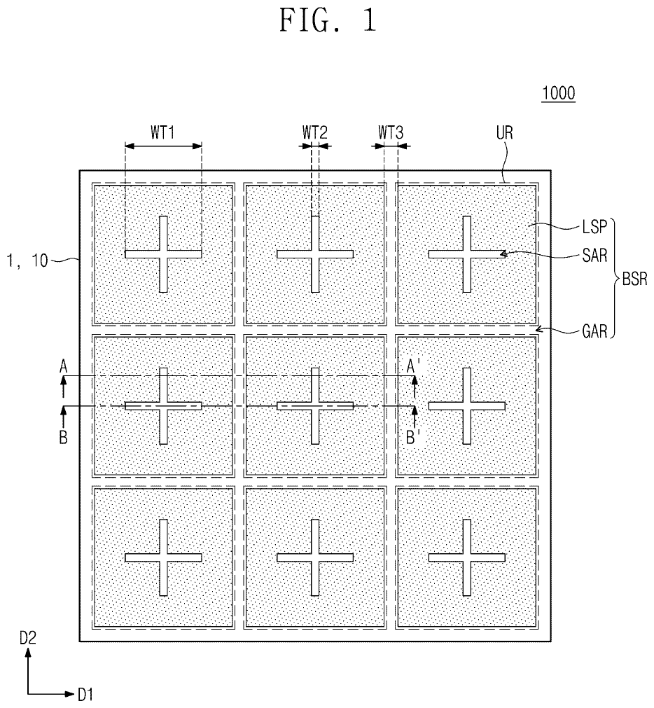

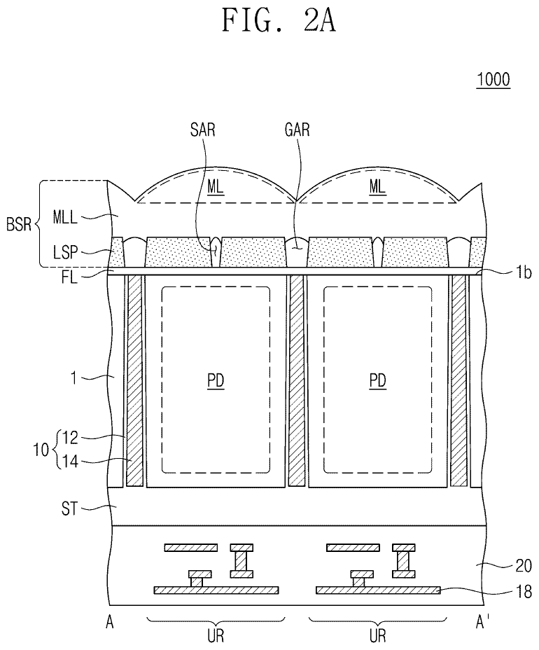

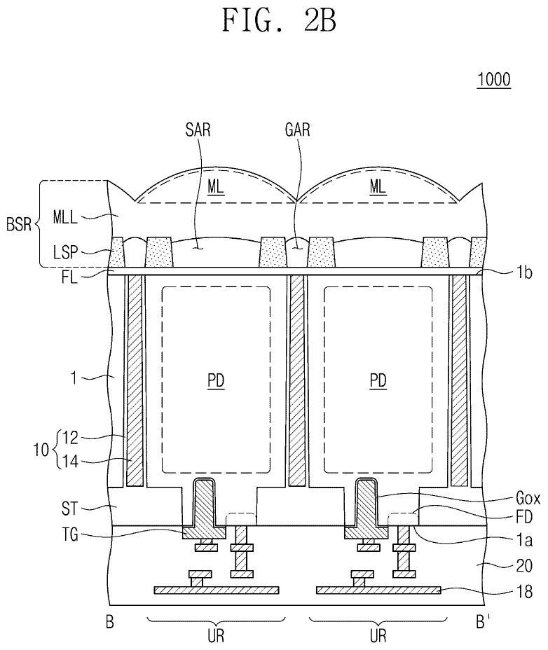

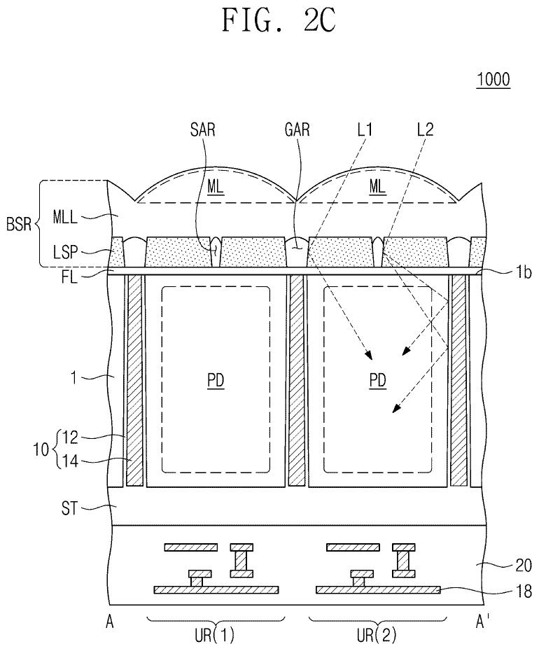

FIG. 1 is a plan view illustrating an exemplary image sensor according to an embodiment of this disclosure. FIG. 2A is a sectional view along a line A-A′ of FIG. 1 and FIG. 2B is a sectional view along a line B-B′ of FIG. 1.

Referring to FIGS. 1, 2A, and 2B, an image sensor 1000 may be provided. In some embodiments, the image sensor 1000 may be referred to as an infrared sensor or an optical sensor. The image sensor 1000 may include a substrate 1. The substrate 1 may include a front surface 1a and a rear surface 1b, which are opposite to each other. Light may be incident into the substrate 1 through the rear surface 1b. In some embodiments, the substrate 1 may be a single crystalline wafer, which is formed of or includes silicon and/or germanium, an epitaxial layer, or a silicon-on-insulator (SOI) wafer. The substrate 1 may be doped with a first impurity of a first conductivity type. The first conductivity type may be, for example, a p-type. The first impurity may be, for example, boron.

A photodiode isolation pattern 10 may be disposed in the substrate 1 to define multiple light-receiving regions UR which are separated from each other. The photodiode isolation pattern 10 may have a mesh shape, when viewed in a plan view. The photodiode isolation pattern 10 may be provided to penetrate the substrate 1 and isolate the light-receiving regions UR. In some embodiments, the light-receiving regions UR and the photodiode isolation pattern 10 may be formed on the front surface 1a of the substrate 1.

In some embodiments, the photodiode isolation pattern 10 may include an isolation conductive pattern 14 and an isolation insulating pattern 12 (as shown in FIG. 2A). The isolation conductive pattern 14 may be spaced apart from the substrate 1. The isolation conductive pattern 14 may include a conductive material having a refractive index different from a refractive index of the substrate 1. The isolation conductive pattern 14 may be formed of or include, for example, doped polysilicon or metallic materials. A negative bias voltage may be applied to the isolation conductive pattern 14. The isolation conductive pattern 14 may serve as a common bias line. Thus, holes, which may be present on a surface of the substrate 1 in contact with the photodiode isolation pattern 10, may be immobilized, and the dark current property of the image sensor may be improved.

The isolation insulating pattern 12 may be interposed between the isolation conductive pattern 14 and the substrate 1. The isolation insulating pattern 12 may include an insulating material having a refractive index different from a refractive index of the substrate 1. For example, the isolation insulating pattern 12 may be formed of or include silicon oxide.

A shallow trench isolation pattern ST may be disposed in a portion of the substrate 1, which is adjacent to the front surface 1a of the substrate 1, to define active regions for transistors. The shallow trench isolation pattern ST may be formed by a shallow trench isolation method. The shallow trench isolation pattern ST may be formed of or include at least one of silicon oxide, silicon nitride, or silicon oxynitride and may have a single-layered structure or a multi-layered structure. In the case where the isolation insulating pattern 12 of the photodiode isolation pattern 10 are formed of the same insulating material as the shallow trench isolation pattern ST, there may be no observable or visible interface therebetween.

Alternatively, the shallow trench isolation pattern ST may be an impurity region that is doped with impurities. In this case, the shallow trench isolation pattern ST may be doped with the first impurity to have the first conductivity type that is the same as that of the substrate 1, and it may be formed to have a doping concentration higher than that of the substrate 1.

Referring to FIG. 2B, a transfer transistor TG may be disposed on the front surface 1a of the substrate 1 and in each of the light-receiving regions UR. A portion of the transfer transistor TG may be placed on the front surface 1a of the substrate 1, and another portion of the transfer transistor TG may be inserted into the substrate 1. A gate insulating layer Gox may be interposed between the transfer transistor TG and the substrate 1. The gate insulating layer Gox may be formed of or include at least one of silicon oxide, metal oxide, silicon nitride, or silicon oxynitride and may have a single-layered structure or a multi-layered structure. A floating diffusion region FD may be disposed in a portion of the substrate 1 next to the transfer transistor TG. The floating diffusion region FD may be doped with a second impurity having a second conductivity type, different from the first conductivity type. The second conductivity type may be, for example, an n-type, and the second impurity may be phosphorus or arsenic.

An interlayer insulating layer 20 may be disposed on the front surface 1a of the substrate 1 to cover the transfer transistor TG. The interlayer insulating layer 20 may be formed of or include at least one of silicon oxide, silicon nitride, silicon oxynitride, porous insulating materials, or silicon carbon nitride (SiCN) and may have a single-layered or a multi-layered structure. Interconnection lines 18 may be disposed in the interlayer insulating layer 20.

In each of the light-receiving regions UR, a photodiode PD may be disposed in the substrate 1. The photodiode PD may be doped with a second impurity of a second conductivity type which is different from the first conductivity type. The second conductivity type may be an n-type, and the second impurity may be phosphorus or arsenic. The photodiode PD may be the n-type impurity region, and the photodiode PD and the p-type impurity region of the substrate 1 may form a p-n junction serving as a photodiode. In the case where light is incident on the p-n junction, electron-hole pairs may be generated in the p-n junction.

The rear surface 1b of the substrate 1 may be covered with a fixed charge layer FL (e.g., as shown in FIG. 2B). The fixed charge layer FL may be in contact with the rear surface 1b. The fixed charge layer FL may be formed of a metal oxide layer, whose oxygen content is lower than its stoichiometric ratio, or a metal fluoride layer, whose fluorine content ratio is lower than its stoichiometric ratio. Thus, the fixed charge layer FL may have negative fixed charges. The fixed charge layer FL may be formed of metal oxide or metal fluoride containing at least one metal, which is selected from the group consisting of hafnium (Hf), zirconium (Zr), aluminum (Al), tantalum (Ta), titanium (Ti), yttrium (Y), and lanthanoid. The hole accumulation may occur near the fixed charge layer FL. In this case, it may be possible to effectively suppress the dark current issue and the white spot issue. In some embodiments, the fixed charge layer FL may be formed of or include at least one of aluminum oxide or hafnium oxide and may have a single-layered structure or a multi-layered structure.

A back-side structure BSR may be disposed on the fixed charge layer FL. At least one of an anti-reflection layer, a planarization layer, and a protection layer may be additionally interposed between the fixed charge layer FL and the back-side structure BSR. The back-side structure BSR may include a grid air region GAR and light-scattering air regions SAR. The grid air region GAR and the light-scattering air regions SAR may refer to unfilled or empty spaces. The grid air region GAR may have a grid shape when viewed in the plan view, as shown in FIG. 1. For example, the grid shape of the grid air region may refer to an arrangement including a plurality of columns of the grid air region intersected by a plurality of rows of the grid air region forming square grid air region shapes disposed adjacent to each other. In some embodiments, the grid air region GAR may overlap with the photodiode isolation pattern 10 and the light-scattering air regions SAR may overlap with the light-receiving regions UR. Each of the light-scattering air regions SAR may be enclosed by the grid air region GAR, when viewed in the plan view, as shown in FIG. 1.

In some embodiments, each of the light-scattering air regions SAR may have a cross shape, when viewed in a plan view. Each of the light-scattering air regions SAR may have at most, a first width WT1 in a first direction D1 and at least, a second width WT2 in the first direction D1. The grid air region GAR may have a third width WT3 in the first direction D1 on the photodiode isolation pattern 10. The third width WT3 may be smaller than the first width WT1. The third width WT3 may be equal to or different from the second width WT2. For example, the third width WT3 may be larger than the second width WT2. The first width WT1 may be equal to a wavelength of light incident on the light-receiving regions UR or may range from 0.9 to 1.1 times the wavelength of incident light.

With reference to FIG. 2A, the back-side structure BSR may include light-transparent patterns LSP and a micro lens layer MLL. The light-transparent patterns LSP may overlap with the light-receiving regions UR, respectively. The light-transparent patterns LSP may have a rectangular shape, when viewed in a plan view, as shown in FIG. 1. In some embodiments, an empty (i.e., unfilled) space between adjacent light-transparent patterns LSP may be referred to as the grid air region GAR. The light-scattering air region SAR may be disposed in each of the light-transparent patterns LSP. In some embodiments, the border of the grid air region GAR and the border of the light-scattering air regions SAR may be defined by the light-transparent patterns LSP. A bottom portion of the grid air region GAR and bottom portions of the light-scattering air regions SAR may be defined by the fixed charge layer FL.

A refractive index of a material constituting the back-side structure BSR may be higher than refractive indices of the grid air region GAR and the light-scattering air regions SAR. Each of the light-transparent patterns LSP may be formed of an optically transparent material having a refractive index higher than those of the grid air region GAR and the light-scattering air regions SAR. The grid air region GAR and the light-scattering air regions SAR may have a refractive index of 1, and a material constituting the light-transparent patterns LSP may have a refractive index, for example, ranging from 1.4 to 1.6. The light-transparent patterns LSP may be formed of, for example, low-density silicon oxide, a photoimageable dielectric (PID) material, or a photoresist material. In some embodiments, the material constituting the light-transparent patterns LSP may have a lower density than a material constituting the isolation insulating pattern 12.

The micro lens layer MLL may cover the light-transparent patterns LSP. The micro lens layer MLL may constitute a top portion of the grid air region GAR and top portions of the light-scattering air regions SAR. On the grid air region GAR and the light-scattering air regions SAR, the micro lens layer MLL may have a bottom surface that is convex in an upward direction. A material constituting the micro lens layer MLL may have a refractive index of about 1.6. The material constituting the micro lens layer MLL may be the same as the material constituting the light-transparent patterns LSP. In this case, there may be no observable or visible interface between the micro lens layer MLL and the light-transparent patterns LSP. The micro lens layer MLL may include top portions, which are convex and are used as micro lenses ML. The micro lenses ML may overlap with the light-receiving regions UR, respectively. In some embodiments, a single micro lens ML may be provided to cover a plurality of light-receiving regions UR.

FIG. 2C is a diagram illustrating a propagation path of light that is incident on the image sensor of FIG. 2A, consistent with some embodiments of the present disclosure.

Referring to FIG. 2C, the light-receiving regions UR may include a first light-receiving region UR(1) and a second light-receiving region UR(2) adjacent to the first light-receiving region UR(1). In some embodiments, a first light L1 may be incident on a portion of the light-transparent pattern LSP through the micro lens ML on the second light-receiving region UR(2). The first light L1 may be obliquely incident, as illustrated in FIG. 2C. Due to a difference in refractive index between the light-transparent pattern LSP and the grid air region GAR, the first light L1 may be reflected or refracted by the outermost side surface of the light-transparent pattern LSP or at a boundary between the light-transparent pattern LSP and the grid air region GAR and may be incident into the photodiode PD in the second light-receiving region UR(2). The grid air region GAR may prevent the first light L1 from being incident on the first light-receiving region UR(1) adjacent to the second light-receiving region UR(2), and therefore, it may be possible to prevent a cross-talk between adjacent light-receiving regions UR.

Referring to FIG. 2C, a second light L2 may be incident into the light-transparent pattern LSP through the micro lens ML on the second light-receiving region UR(2). The second light L2 may be obliquely incident. Due to a difference in refractive index between the light-transparent pattern LSP and the light-scattering air region SAR, the second light L2 may be reflected, refracted, or scattered by an inner side surface of the light-transparent pattern LSP or at a boundary between the light-transparent pattern LSP and the light-scattering air region SAR and may be incident on the photodiode PD in the second light-receiving region UR(2). The second light L2 may be reflected, refracted, or scattered by a side surface of the photodiode isolation pattern 10 and may be incident on the photodiode PD. In such a configuration, the light-scattering air region SAR may be used as an optical splitter.

In some embodiments, the first light L1 and the second light L2 may comprise infrared (IR) light or visible red light with a relatively long wavelength. In the case where the first and second lights L1 and L2 have a long wavelength, they may exhibit low absorption within the substrate 1, and a low quantum efficiency. In the context of this disclosure, quantum efficiency refers to the fraction of light converted into electric charges. In the image sensor 1000, in some embodiments, due to the light-scattering air region SAR, the second light L2 may be split into multiple rays traveling along various optical paths and scattering within the substrate 1. This may make it possible to realize multiple reflections and increase the optical path. Therefore, the absorption of the second light L2 may be increased, and the quantum efficiency may be increased. Accordingly, the modulation transfer function (MTF) characteristics of the image sensor may be improved.

In the image sensor 1000, since the light-scattering air region SAR serving as the optical splitter is not disposed in the substrate 1, it may not be necessary to additionally etch the substrate 1 to form the light-scattering air region SAR, and since the substrate 1 is additionally etched, the substrate 1 may have no etch damage. Accordingly, it may be possible to minimize the formation of dangling bonds, to suppress the dark current issue and the white spot issue, to improve the dark level characteristics, and to realize clear images.

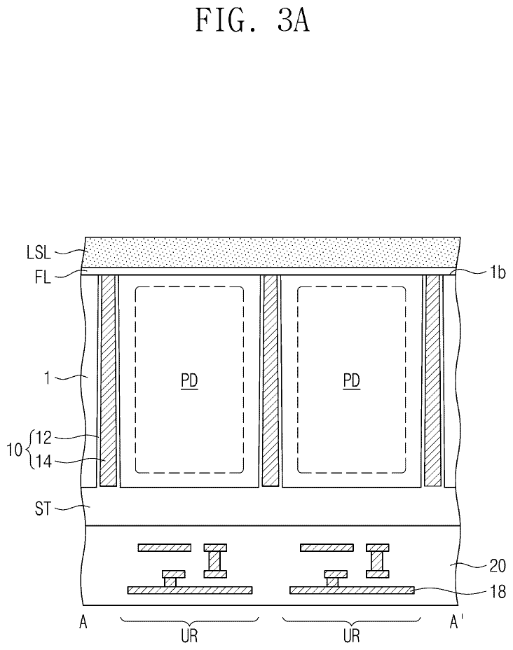

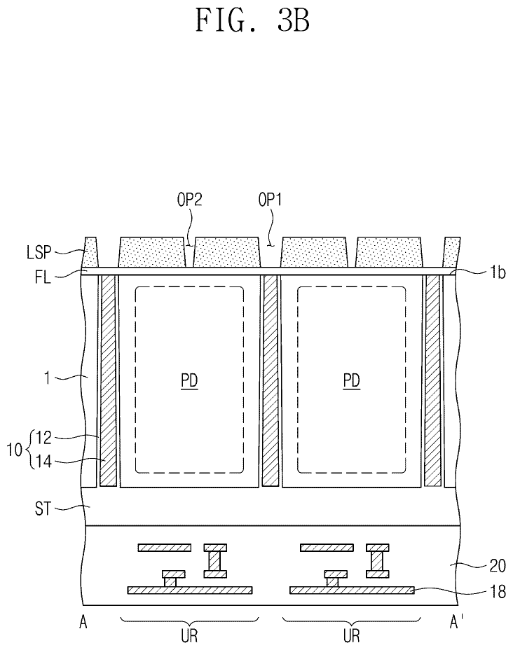

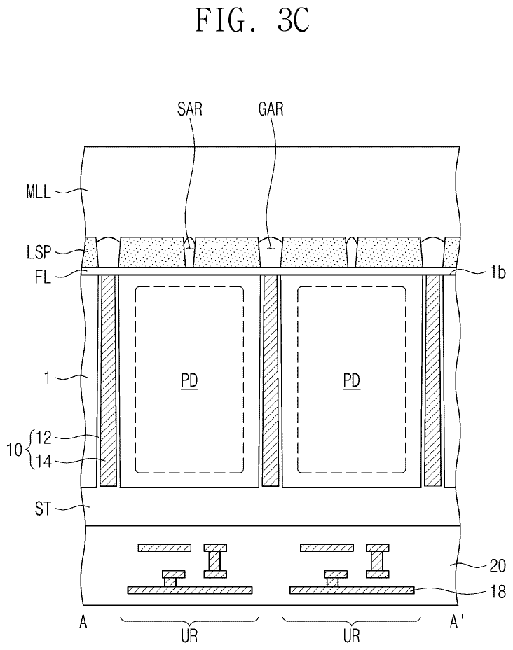

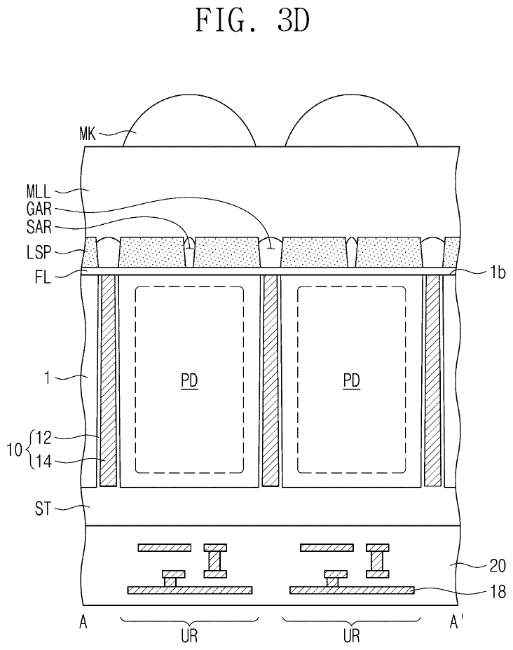

FIGS. 3A to 3D are sectional views illustrating a process of fabricating an image sensor with the section of FIG. 2A, consistent with some embodiments of the present disclosure.

Referring to FIGS. 2B and 3A, the photodiode isolation pattern 10 may be formed in the substrate 1 to define the light-receiving regions UR. The photodiode PD may be formed in the substrate 1. The shallow trench isolation pattern ST, the transfer transistor TG, the floating diffusion region FD may be formed adjacent to the front surface 1a of the substrate 1. The interlayer insulating layer 20 may be formed on the front surface 1a of the substrate 1, and the interconnection lines 18 may be formed in the interlayer insulating layer 20. The fixed charge layer FL may be formed on the rear surface 1b of the substrate 1. A light-transparent layer LSL may be formed on the fixed charge layer FL. In the case where the light-transparent layer LSL is formed of low-density silicon oxide, it may be formed by a deposition process. In the case where the light-transparent layer LSL is formed of a photoimageable dielectric (PID) material or a photoresist material, it may be formed by a coating and baking process.

Referring to FIG. 3B, the light-transparent layer LSL may be patterned to form the light-transparent patterns LSP with first and second openings OP1 and OP2. The first opening OP1 may have a grid shape and may overlap with the photodiode isolation pattern 10, when viewed in a plan view. The second opening OP2 may have a cross shape, when viewed in a plan view. The first opening OP1 may correspond to the grid air region GAR of FIGS. 1 and 2A. The second opening OP2 may correspond to the light-scattering air region SAR of FIGS. 1 and 2A. In the case where the light-transparent layer LSL is formed of silicon oxide, the patterning of the light-transparent layer LSL may be performed by an etching process. In the case where the light-transparent layer LSL is formed of a PID or photoresist material, the patterning of the light-transparent layer LSL may be performed by a photolithography (e.g., exposing and developing) process.

Referring to FIG. 3C, the micro lens layer MLL may be formed on the light-transparent patterns LSP. In some embodiments, the micro lens layer MLL may be formed of a transparent photoresist material, a transparent thermosetting resin, or a transparent insulating material. In some embodiments, the micro lens layer MLL may be formed of a material having a poor gapfill property or may be formed by a process with a poor gapfill property. The micro lens layer MLL may cover the top of each of the first and second openings OP1 and OP2 of the light-transparent patterns LSP and may not fill the entirety of each of the first and second openings OP1 and OP2. As a result, the grid air region GAR and the light-scattering air regions SAR may be formed.

Referring to FIG. 3D, mask patterns MK may be formed on the micro lens layer MLL. The mask patterns MK may be formed by performing a photolithography process to form photoresist patterns and performing a reflow process on the photoresist patterns. The mask patterns MK may be formed to have a hemisphere-like shape, although the shape of the mask patterns is not limited to hemisphere-like shapes.

Referring back to FIG. 2A, an etch-back process may be performed on the micro lens layer MLL. Here, the mask patterns MK may also be etched. The shape of the mask patterns MK may be transferred to the micro lens layer MLL, and as a result, the micro lenses ML having a convex shape may be formed in an upper portion of the micro lens layer MLL. As a result, the image sensor 1000 may be fabricated to have the same structure as shown in FIGS. 1 to 2B.

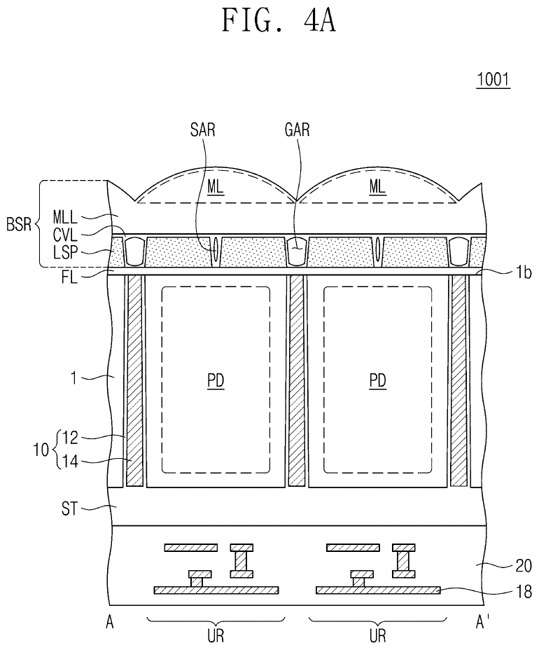

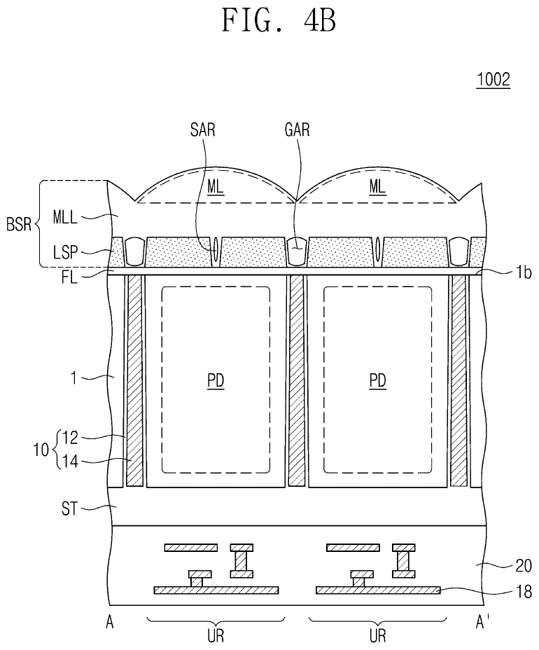

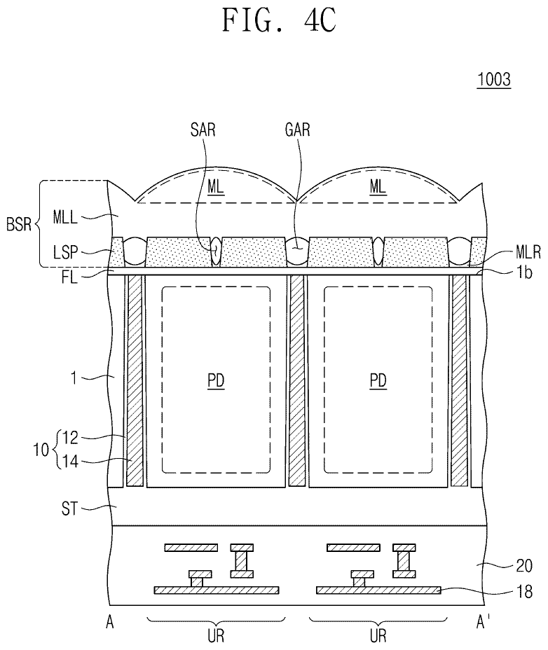

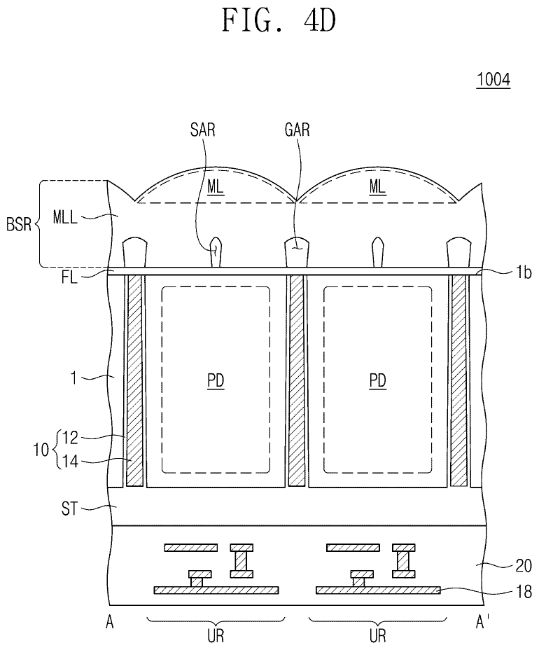

FIGS. 4A to 4D illustrate sectional views of exemplary image sensors, consistent with some embodiments of the present disclosure.

Referring to FIG. 4A, the back-side structure BSR of image sensor 1001 may further include a cover layer CVL interposed between the light-transparent patterns LSP and the micro lens layer MLL. In some embodiments, the cover layer CVL may be formed of a material having a poor gapfill property or may be formed by a process with a poor gapfill property. The cover layer CVL may be formed of or include at least one of, for example, silicon oxide or photoresist materials. The cover layer CVL may cover side surfaces of the light-transparent patterns LSP and a top surface of the fixed charge layer FL. The grid air region GAR and the light-scattering air regions SAR may be formed in the cover layer CVL. Except for the afore-described features, other portions of the image sensor may be configured to have the same or similar features as the embodiments described with reference to FIGS. 1 to 2B.

Referring to FIG. 4B, in an image sensor 1002, a portion of the micro lens layer MLL in the back-side structure BSR may be inserted into a region between the light-transparent patterns LSP to cover side surfaces of the light-transparent patterns LSP and a top surface of the fixed charge layer FL. The grid air region GAR and the light-scattering air regions SAR may be formed in the micro lens layer MLL, between the light-transparent patterns LSP. Except for the afore-described features, other portions of the image sensor may be configured to have the same or similar features as the embodiments described with reference to FIGS. 1 to 2B.

Referring to FIG. 4C, in an image sensor 1003, a top surface of the fixed charge layer FL between the light-transparent patterns LSP in the back-side structure BSR, may be covered with a lens residue pattern MLR. The lens residue pattern MLR may be formed of or include the same material as the micro lens layer MLL. The grid air region GAR and the light-scattering air regions SAR may be provided to expose the side surfaces of the light-transparent patterns LSP. Except for the afore-described features, other portions of the image sensor may be configured to have the same or similar features as the embodiments described with reference to FIGS. 1 to 2B.

Referring to FIG. 4D, in an image sensor 1004, the back-side structure BSR may not include the light-transparent patterns LSP of FIG. 2A. The grid air region GAR and the light-scattering air regions SAR may be formed in the micro lens layer MLL. Except for the afore-described features, other portions of the image sensor may be configured to have the same or similar features as the embodiments described with reference to FIGS. 1 to 2B.

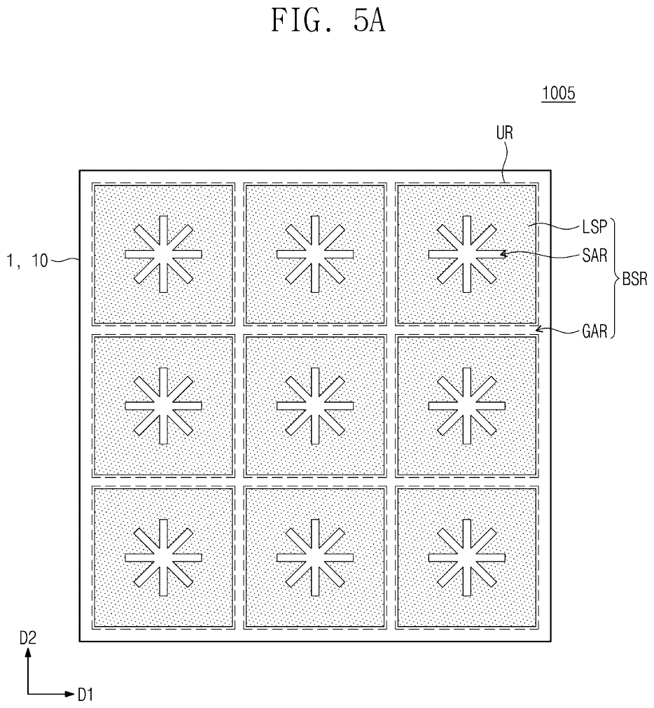

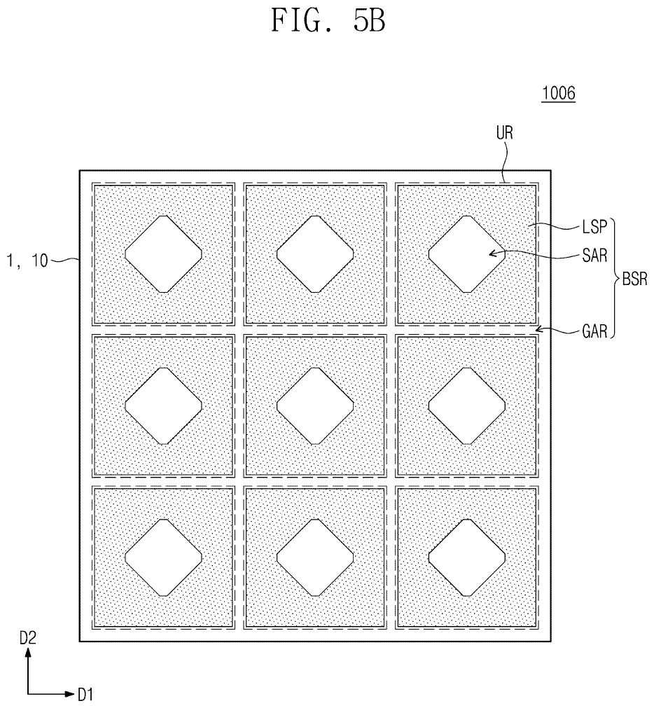

FIGS. 5A and 5B illustrate plan views of exemplary image sensors, consistent with some embodiments of the present disclosure.

Referring to FIG. 5A, in an image sensor 1005, each of the light-scattering air regions SAR may have a star shape, when viewed in a plan view. Referring to FIG. 5B, in an image sensor 1006, each of the light-scattering air regions SAR may have an octagonal shape, when viewed in a plan view. The planar shape of each of the light-scattering air regions SAR is not limited to this example and may have a polygonal shape with three or more vertices.

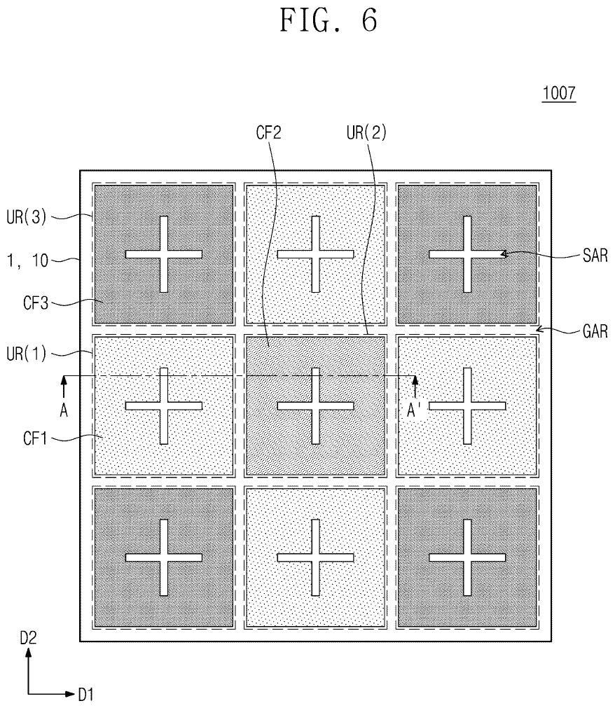

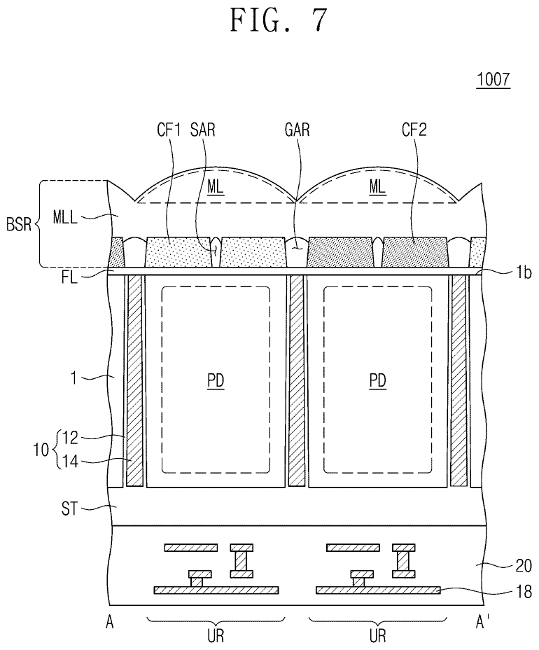

FIG. 6 illustrates a plan view of an exemplary image sensor, consistent with some embodiments of the present disclosure. FIG. 7 illustrates a sectional view along a line A-A′ of FIG. 6.

Referring to FIGS. 6 and 7, an image sensor 1007 may correspond to the image sensor 1000 of FIG. 2A, in which the light-transparent patterns LSP are provided to contain a coloring agent. In other words, the light-transparent patterns LSP of the image sensor 1000 of FIG. 2A may correspond to color filters CF1 to CF3. In some embodiments, the light-receiving regions UR may include a first light-receiving region UR(1), a second light-receiving region UR(2), and a third light-receiving region UR(3). The first light-receiving region UR(1) may be a region for detecting light of first color. The second light-receiving region UR(2) may be a region for detecting light of second color. The third light-receiving region UR(3) may be a region for detecting light of third color. In some embodiments, a first color filter CF1 may be disposed on the first light-receiving region UR(1), a second color filter CF2 may be disposed on the second light-receiving region UR(2), and a third color filter CF3 may be disposed on the third light-receiving region UR(3).

The first to third color filters CF1 to CF3 may include a photoresist material containing a coloring agent (e.g., dye or pigment). Each of the first to third color filters CF1 to CF3 may have a blue, red, or green color. Alternatively, each of the first to third color filters CF1 to CF3 may have a cyan, yellow, or magenta color. In some embodiments, one of the first to third color filters CF1 to CF3 may not contain any coloring agent and may be formed of a portion of the micro lens layer MLL.

The grid air region GAR may be present between the first to third color filters CF1 to CF3. The light-scattering air regions SAR may be present in the first to third color filters CF1 to CF3, respectively. FIG. 6 illustrates an example in which the light-scattering air regions SAR of the first to third color filters CF1 to CF3 have the same cross shape, the same width, and the same size in a plan view, but the disclosure is not limited to this example. The light-scattering air regions SAR of the first to third color filters CF1 to CF3 may differ in their planar shapes, widths, and sizes. Except for the afore-described features, other portions of the image sensor may be configured to have the same or similar features as the embodiments described with reference to FIGS. 1 to 5B.

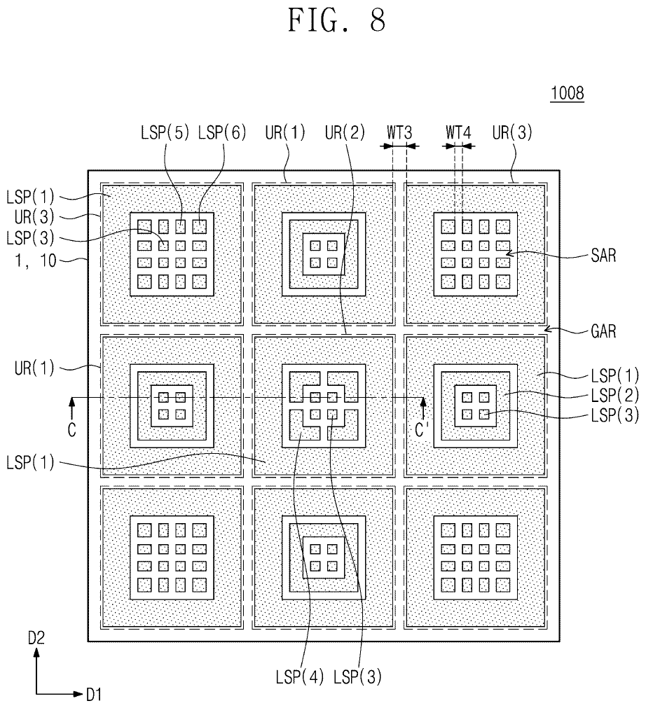

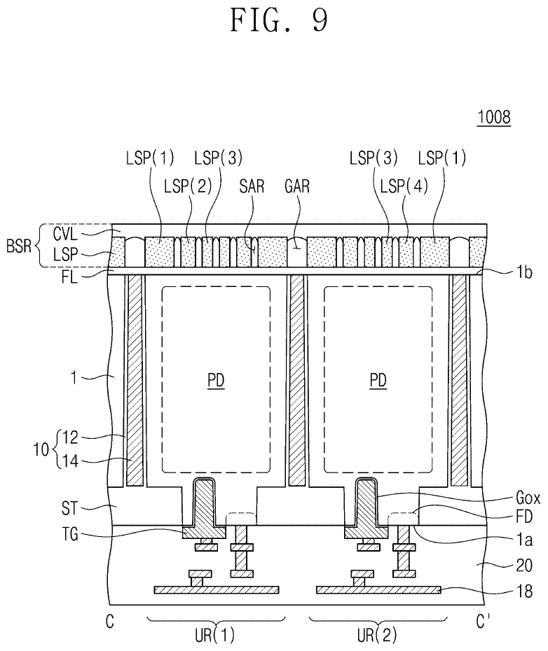

Reference is now made to FIG. 8, which illustrates a plan view of an exemplary image sensor, consistent with some embodiments of the present disclosure. FIG. 9 illustrates a sectional view along a line C-C′ of FIG. 8.

Referring to FIGS. 8 and 9, in an image sensor 1008, the back-side structure BSR may include the light-transparent patterns LSP and the cover layer CVL but may not include the micro lens layer MLL of FIG. 2A. A plurality of light-transparent patterns LSP may be disposed on each light-receiving region UR. The light-scattering air regions SAR may be provided between the light-transparent patterns LSP, on each light-receiving region UR. The light-scattering air regions SAR may have a fourth width WT4. The fourth width WT4 may correspond to a distance between the light-transparent patterns LSP on each light-receiving region UR. In some embodiments, the fourth width WT4 may be smaller than a wavelength of light that is incident on the light-receiving regions UR. Each of the light-transparent patterns LSP may have various shapes (e.g., closed curve, letter ‘L’, rectangular, square, elliptical, or circular shapes), when viewed in a plan view. The light-transparent patterns LSP may have widths and lengths that are different from each other. The light-transparent patterns LSP may serve as an optical splitter that is configured to improve cross-talk issues and cause optical scattering. In addition, the light-transparent patterns LSP may serve as a nano-prism configured to adjust the phase distribution of light with the same wavelength, enabling multiple focusing of the light onto a specific target region.

For example, first to third light-transparent patterns LSP(1) to LSP(3) may be disposed on the first light-receiving region UR(1). The first light-transparent pattern LSP(1) may have a closed curve shape and may be provided along an edge of the first light-receiving region UR(1), when viewed in a plan view. Each of the third light-transparent patterns LSP(3) may have a square shape, and a plurality of third light-transparent patterns LSP(3) may be provided on a center portion of the first light-receiving region UR(1), when viewed in a plan view. The second light-transparent pattern LSP(2) may have a closed curve shape and may be disposed between the first light-transparent pattern LSP(1) and the third light-transparent patterns LSP(3), when viewed in a plan view. Each of the first to third light-transparent patterns LSP(1) to LSP(3) on the first light-receiving region UR(1) may be configured to adjust the phase distribution of light with a first wavelength, enabling multiple focusing of the light onto the first light-receiving region UR(1). The light-scattering air regions SAR may be provided between the first to third light-transparent patterns LSP(1) to LSP(3). Each of the light-scattering air regions SAR on the first light-receiving region UR(1) may have a closed curve and/or a grid shape, when viewed in a plan view.

In some embodiments, first, third, and fourth light-transparent patterns LSP(1), LSP(3), and LSP(4) may be disposed on the second light-receiving region UR(2). The first light-transparent pattern LSP(1) may have a closed curve shape and may be provided along an edge of the second light-receiving region UR(2), when viewed in a plan view. Each of the third light-transparent patterns LSP(3) may have a square shape, and a plurality of third light-transparent patterns LSP(3) may be provided on a center portion of the second light-receiving region UR(2), when viewed in a plan view. The fourth light-transparent pattern LSP(4) may have an ‘L’ shape and may be disposed between the first light-transparent pattern LSP(1) and the third light-transparent patterns LSP(3), when viewed in a plan view. Each of the first, third, and fourth light-transparent patterns LSP(1), LSP(3), and LSP(4) on the second light-receiving region UR(2) may be configured to adjust the phase distribution of light with a second wavelength, enabling multiple focusing of the light onto the second light-receiving region UR(2). The light-scattering air regions SAR may be provided between the first, third, and fourth light-transparent patterns LSP(1), LSP(3), and LSP(4). Each of the light-scattering air regions SAR on the second light-receiving region UR(2) may have a grid shape, when viewed in a plan view.

In some embodiments, the first, third, fifth, and sixth light-transparent patterns LSP(1), LSP(3), LSP(5), and LSP(6), respectively, may be disposed on the third light-receiving region UR(3). The first light-transparent pattern LSP(1) may have a closed curve shape and may be provided along an edge of the third light-receiving region UR(3), when viewed in a plan view. Each of the third light-transparent patterns LSP(3) may have a square shape, and a plurality of third light-transparent patterns LSP(3) may be provided on a center portion of the third light-receiving region UR(3), when viewed in a plan view. The fifth light-transparent patterns LSP(5) may have a rectangular shape and may be disposed between the first light-transparent pattern LSP(1) and the third light-transparent patterns LSP(3), when viewed in a plan view. The sixth light-transparent patterns LSP(6) may have a square shape, may be larger than the third light-transparent patterns LSP(3), and may be disposed between the first light-transparent pattern LSP(1) and the fifth light-transparent pattern LSP(5), when viewed in a plan view. Each of the first, third, fifth, and sixth light-transparent patterns LSP(1), LSP(3), LSP(5), and LSP(6) on the third light-receiving region UR(3) may be configured to adjust the phase distribution of light with a third wavelength, enabling multiple focusing of the light onto the third light-receiving region UR(3). The light-scattering air regions SAR may be provided between the first, third, fifth, and sixth light-transparent patterns LSP(1), LSP(3), LSP(5), and LSP(6). Each of the light-scattering air regions SAR on the third light-receiving region UR(3) may have a grid shape, when viewed in a plan view.

Between the light-receiving regions UR, the grid air region GAR may be provided between the first light-transparent patterns LSP(1). The grid air region GAR may have a third width WT3. The cover layer CVL may be disposed on the light-transparent patterns LSP. A top surface of the cover layer CVL may be flat. The cover layer CVL may be formed of at least one of silicon oxide or photoresist materials. In some embodiments, the light-transparent patterns LSP may be used to focus light with a desired wavelength onto a desired region, even in the absence of color filters or infrared filters, and to efficiently focus light, even without the micro lenses ML. In this case, the optical sensitivity of the image sensor may be improved. Except for the afore-described features, other portions of the image sensor may be configured to have the same or similar features as the embodiments described with reference to FIGS. 1 to 5B.

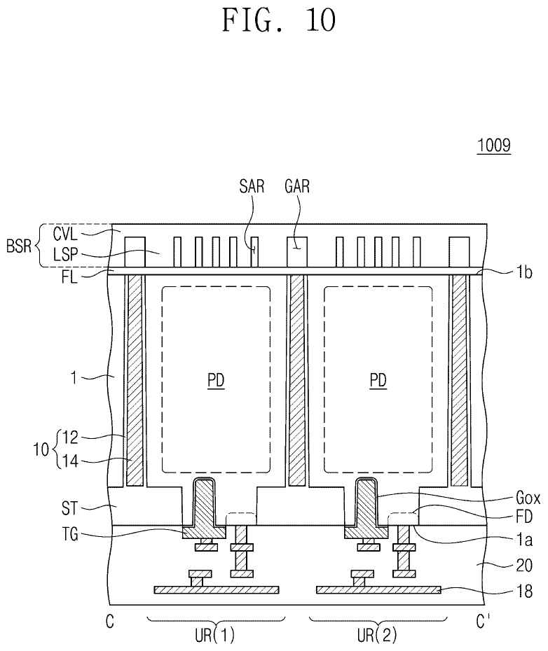

FIG. 10 illustrates a sectional view of an exemplary image sensor, consistent with some embodiments of the present disclosure.

Referring to FIG. 10, an image sensor 1009 may include the back-side structure BSR, which is similar to that of the image sensor 1008 of FIG. 9 and is composed of the cover layer CVL. The light-scattering air regions SAR and the grid air regions GAR may be formed in the cover layer CVL. The light-scattering air regions SAR and the grid air regions GAR may have the same planar shape as in FIG. 8. The image sensor 1009 of FIG. 10 may correspond to the image sensor 1008 of FIG. 9, in which the light-transparent patterns LSP are formed of the same material as the cover layer CVL without an observable interface therebetween. Except for the afore-described features, other portions of the image sensor may be configured to have the same or similar features as the embodiments described with reference to FIGS. 8 and 9.

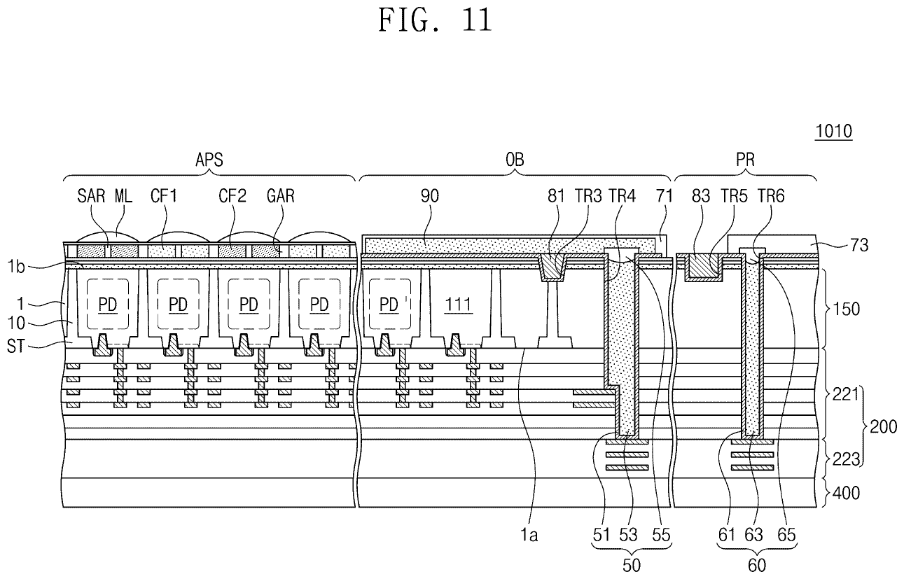

FIG. 11 illustrates a sectional view of an exemplary image sensor, consistent with some embodiments of the present disclosure.

Referring to FIG. 11, an image sensor 1010 may include the substrate 1 with a main region APS, an optical black region OB, and a pad region PR, an interconnection layer 200 on the front surface 1a of the substrate 1, and a base substrate 400 on the interconnection layer 200.

As illustrated, the interconnection layer 200 may include an upper interconnection layer 221 and a lower interconnection layer 223. The main region APS may include the light-receiving regions UR described with reference to FIGS. 1 to 7.

A first connection structure 50, a first conductive pad 81, and a bulk color filter 90 may be provided in the optical black region OB and on the substrate 1. The first connection structure 50 may include a first light-blocking pattern 51, an insulating pattern 53, and a first capping pattern 55. The first light-blocking pattern 51 may be formed of a conductive material. The first light-blocking pattern 51 may be formed of or include, for example, titanium or tungsten.

The first light-blocking pattern 51 may be provided on the rear surface 1b of the substrate 1. The first light-blocking pattern 51 may conformally cover inner surfaces of third and fourth trenches TR3 and TR4. The first light-blocking pattern 51 may be provided to penetrate a photoelectric conversion layer 150 and the upper interconnection layer 221 and to connect the photoelectric conversion layer 150 to the interconnection layer 200.

The first light-blocking pattern 51 may be in contact with the isolation conductive pattern 14 of the photodiode isolation pattern 10 of FIG. 2A. The first conductive pad 81 may be electrically connected to the isolation conductive pattern 14 of the photodiode isolation pattern 10. The first light-blocking pattern 51 may block light, which is incident on the optical black region OB.

The first conductive pad 81 may be provided in the third trench TR3 to fill a remaining portion of the third trench TR3. The first conductive pad 81 may be formed of or include at least one of metallic materials such as, but not limited to, aluminum. A negative bias voltage may be applied to the isolation conductive pattern 14 through the first conductive pad 81. In some embodiments, it may be possible to prevent or suppress a white spot issue or a dark current issue.

The insulating pattern 53 may fill a remaining portion of the fourth trench TR4. The insulating pattern 53 may be formed to penetrate the photoelectric conversion layer 150 and the entirety or at least a portion of the interconnection layer 200. The first capping pattern 55 may be provided on a top surface of the insulating pattern 53. The first capping pattern 55 may be provided on the insulating pattern 53.

In some embodiments, the bulk color filter 90 may be provided on the first conductive pad 81, a first light-blocking pattern 51, and a first capping pattern 55. The bulk color filter 90 may cover the first conductive pad 81, the first light-blocking pattern 51, and the first capping pattern 55. In some embodiments, a first protection layer 71 may be provided on the bulk color filter 90 to hermetically seal the bulk color filter 90.

A plurality of detection regions may be disposed in the optical black region OB, and a first reference photodiode PD′ and a second reference region 111 may be disposed in the detection regions. The first reference photodiode PD′ may be used to obtain a first reference charge amount, which refers to information on an amount of electric charges generated in a light-blocking state. The first reference charge amount may be used as a reference value for comparison with an amount of charges generated in the light-receiving regions UR. The second reference region 111 may be used to obtain a second reference charge amount, which refers to information on an amount of electric charges generated when the photodiode PD is absent. The second reference charge amount may be used as information to remove process noise.

In the pad region PR, a second connection structure 60, a second conductive pad 83, and a second protection layer 73 may be provided on the substrate 1. In some embodiments, the second connection structure 60 may include a second light-blocking pattern 61, an insulating pattern 63, and a second capping pattern 65.

The second light-blocking pattern 61 may be provided on the rear surface 1b of the substrate 1. The second light-blocking pattern 61 may conformally cover inner surfaces of fifth and sixth trenches TR5 and TR6. The second light-blocking pattern 61 may be provided to penetrate the photoelectric conversion layer 150 and the upper interconnection layer 221 and to connect the photoelectric conversion layer 150 to the interconnection layer 200. The second light-blocking pattern 61 may be in contact with the interconnection lines in the lower interconnection layer 223. The second light-blocking pattern 61 may be electrically connected to the interconnection lines in the interconnection layer 200. The second light-blocking pattern 61 may be formed of or include at least one metallic material such as, but not limited to, titanium or tungsten.

The second conductive pad 83 may be provided in the fifth trench TR5 to fill a remaining portion of the fifth trench TR5. The second conductive pad 83 may be formed of or include at least one metallic material (e.g., aluminum). The second conductive pad 83 may be used as a conduction path for electric connection to the outside of the image sensor. The insulating pattern 63 may fill a remaining portion of the sixth trench TR6. The insulating pattern 63 may be provided to penetrate the photoelectric conversion layer 150 and the entirety or at least a portion of the interconnection layer 200. The second capping pattern 65 may be provided on the insulating pattern 63. The second protection layer 73 may cover a portion of the second light-blocking pattern 61 and the second capping pattern 65.

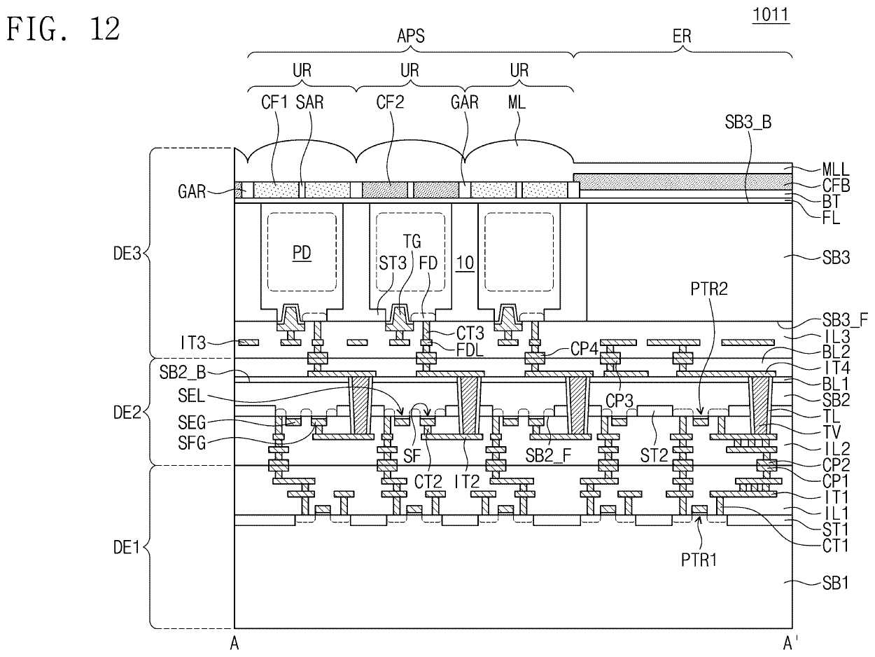

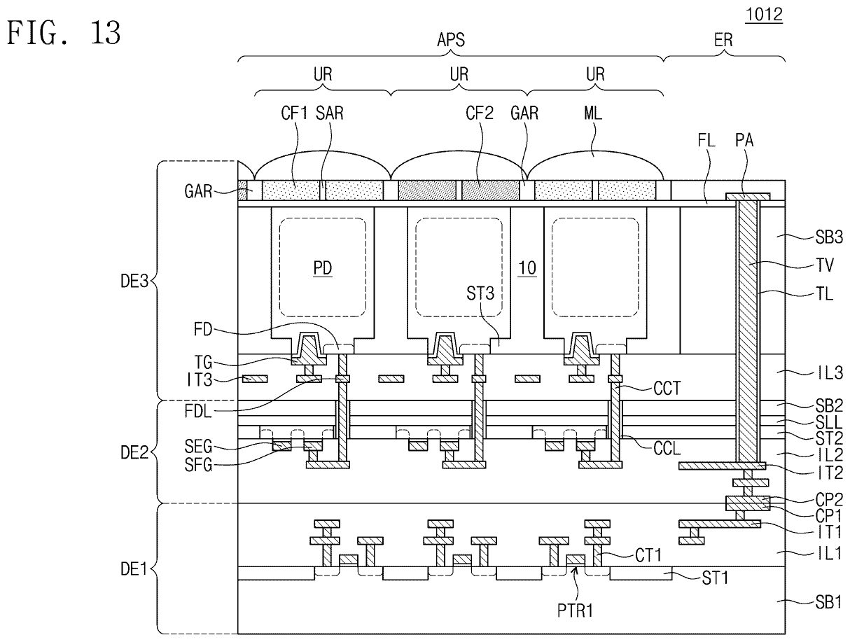

The structure of the image sensor described with reference to FIGS. 1 to 10 may be applied to an image sensor with a 3-chip structure, as illustrated in FIGS. 12 and 13.

FIG. 12 illustrates a sectional view of an image sensor, consistent with some embodiments of the present disclosure.

Referring to FIG. 12, an image sensor 1011 may have a structure, in which first to third sub-chips DE1 to DE3 are sequentially stacked. The ‘chip’ may be referred to as a ‘die.’ The first sub-chip DE1 may include a first substrate SB1 and a first interlayer insulating layer IL1 covering a front surface thereof. The first substrate SB1 may be a semiconductor substrate or an insulating substrate. The first interlayer insulating layer IL1 may be formed of or include at least one of SiO₂, SiN, SiCN, SiON, or SiOCH and may have a single-layered or a multi-layered structure. Logic circuits may be disposed in the first sub-chip DE1. The logic circuits may include, but are not limited to, a row driver, a row decoder, a column decoder, a timing generator, a correlated double sampler (CDS), and/or an analog-to-digital converter (ADC). First peripheral transistors PTR1, first contact plugs CT1, and first interconnection lines IT1 may be disposed on the first substrate SB1 to constitute the logic circuits. A first shallow trench isolation pattern ST1 may be disposed in the first substrate SB1 to define active regions for the first peripheral transistors PTR1. First conductive pads CP1 may be disposed in a top portion of the first interlayer insulating layer IL1.

The second sub-chip DE2 may be placed on and bonded to the first sub-chip DE1. The second sub-chip DE2 may include a second substrate SB2. A front surface SB2_F of the second substrate SB2 may be covered with a second interlayer insulating layer IL2. The front surface SB2_F of the second substrate SB2 may face the first sub-chip DE1. In a main region of the second sub-chip DE2, reset transistors, dual conversion gain transistors, selection transistors SEL including selection gate electrodes SEG, and source follower transistors SF including source follower gate electrodes SFG may be disposed on the front surface SB2_F of the second substrate SB2.

In an edge region of the second sub-chip DE2, second peripheral transistors PTR2 may be disposed on the front surface SB2_F of the second substrate SB2. A second shallow trench isolation pattern ST2 may be disposed in a portion of the second substrate SB2 near the front surface SB2_F to define active regions for the driving transistors (reset transistors, dual conversion gain transistors, source follower transistors, and selection transistors) and the second peripheral transistors PTR2. Second contact plugs CT2 and second interconnection lines IT2 may be disposed in the second interlayer insulating layer IL2. Second conductive pads CP2 may be disposed in a bottom portion of the second interlayer insulating layer IL2. A bottom surface of the second interlayer insulating layer IL2 may be in contact with a top surface of the first interlayer insulating layer IL1. The second conductive pads CP2 may be in contact with the first conductive pads CP1, respectively. Each pair of the first and second conductive pads CP1 and CP2, which are in contact with each other, may form a single object, without an interface therebetween.

A rear surface SB2_B of the second substrate SB2 may be sequentially covered with first and second back-side insulating layers BL1 and BL2. Fourth interconnection lines IT4 may be disposed in the second back-side insulating layer BL2. Third conductive pads CP3 may be disposed in a top portion of the second back-side insulating layer BL2. Penetration vias TV may be provided to penetrate the first back-side insulating layer BL1, the second substrate SB2, the second shallow trench isolation pattern ST2, and a portion of the second interlayer insulating layer IL2 and may be in contact with the second interconnection lines IT2, respectively. The penetration vias TV may have a downward decreasing width. A via insulating layer TL may be interposed between the penetration vias TV and the second substrate SB2.

The third sub-chip DE3 may be placed on and bonded to the second sub-chip DE2. The third sub-chip DE3 may include a third substrate SB3. The third substrate SB3 may include the main region APS and an edge region ER. The main region APS may include a plurality of light-receiving regions UR. The photodiode isolation pattern 10 may be disposed in the third substrate SB3 to separate the light-receiving regions UR from each other. In each of the light-receiving regions UR, the photodiode PD may be disposed in the third substrate SB3. The third substrate SB3 may have a front surface SB3_F facing the second sub-chip DE2. A third shallow trench isolation pattern ST3 may be disposed in a portion of the third substrate SB3 near the front surface SB3_F to define active regions for transfer transistors, each of which includes the transfer transistor TG and the floating diffusion region FD.

The transfer transistor TG and the floating diffusion region FD may be disposed on or near the front surface SB3_F of the third substrate SB3. The front surface SB3_F of the third substrate SB3 may be covered with a third interlayer insulating layer IL3. Third contact plugs CT3, FD interconnection lines FDL, and third interconnection lines IT3 may be disposed in the third interlayer insulating layer IL3. Each of the FD interconnection lines FDL may be provided to connect at least two of the floating diffusion regions FD in adjacent ones of the light-receiving regions UR. The floating diffusion regions FD of the third sub-chip DE3 may be connected to the source follower gate electrodes SFG of the source follower transistors SF of the second sub-chip DE2.

A bottom surface of the third interlayer insulating layer IL3 may be in contact with a top surface of the second back-side insulating layer BL2 of the second sub-chip DE2. Fourth conductive pads CP4 may be disposed in a bottom portion of the third interlayer insulating layer IL3. The fourth conductive pads CP4 may be in contact with the third conductive pads CP3, respectively. Each pair of the third and fourth conductive pads CP3 and CP4, which are in contact with each other, may form a single object, without an interface therebetween.

A rear surface SB3_B of the third substrate SB3 may be covered with the fixed charge layer FL. In the main region APS, the color filters CF1 and CF2 and the micro lenses ML may be disposed on the fixed charge layer FL to define the grid air regions GAR and the light-scattering air regions SAR. In the edge region ER, a first optical black pattern BT, a second optical black pattern CFB, and the micro lens layer MLL may be sequentially disposed on the fixed charge layer FL. The first optical black pattern BT may be formed of or include, but is not limited to, a metallic material such as titanium or tungsten. The second optical black pattern CFB may be composed of a blue color filter. The micro lens layer MLL may be formed of or include the same material as the micro lenses ML. Except for the afore-described features, other portions of the image sensor may be configured to have the same or similar features as the previous embodiments.

FIG. 13 illustrates a sectional view of an exemplary image sensor, consistent with some embodiments of the present disclosure.

Referring to FIG. 13, the image sensor 1012 according to the present embodiment may have a structure in which first to third sub-chips DE1 to DE3 are sequentially stacked. The first sub-chip DE1 may be provided to have the same or similar structure as described with reference to FIG. 12. The second sub-chip DE2 and the third sub-chip DE3 may have a structure similar to that in the embodiment of FIG. 12. The second substrate SB2 may be a semiconductor substrate, an insulating substrate, or a silicon-on-insulator (SOI) substrate. The first conductive pads CP1 may be disposed on a top portion of the first sub-chip DE1.

A substrate insulating layer SLL may be disposed in the second substrate SB2 of the second sub-chip DE2. A penetration contact plug CCT may be provided to penetrate the second substrate SB2, a portion of the second interlayer insulating layer IL2, and a portion of the third interlayer insulating layer IL3 and to connect the FD interconnection lines FDL to the source follower gate electrodes SFG. A penetration contact insulating layer CCL may be interposed between the penetration contact plug CCT and the second substrate SB2. The second conductive pads CP2 may be disposed in a bottom portion of the second sub-chip DE2. The second conductive pads CP2 may be in contact with the first conductive pads CP1, respectively.

An input/output pad PA may be disposed on the fixed charge layer FL and in the edge region ER of the third sub-chip DE3. The penetration via TV may be provided to penetrate the third substrate SB3 and the third interlayer insulating layer IL3 of the third sub-chip DE3 and the second substrate SB2 and a portion of the second interlayer insulating layer IL2 of the second sub-chip DE2 and to connect the input/output pad PA to the second interconnection lines IT2. Except for the afore-described features, other portions of the image sensor may be configured to have the same or similar features as the embodiment described with reference to FIG. 12. The positions of the conductive pads CP1 to CP4 and the penetration via TV are not limited to those in the embodiments of FIGS. 12 and 13 and may be changed, as appropriate.

In the present specification, the “chips” or “sub-chips” may be defined as stacking structures formed from different semiconductor wafers. Depending on the bonding shape of the chips and the bonding material between them, the boundaries of individual chips may not be clearly visible. However, even in such stacking structures, they may still be individual chips formed from different semiconductor wafers.

In an image sensor according to some embodiments, a back-side structure may include a grid air region, which suppresses a cross-talk issue between adjacent ones of light-receiving regions, and a light-scattering air region, which is overlapped with each of the light-receiving regions and increases the quantum efficiency of the image sensor. Thus, it may be possible to realize a clear image. Furthermore, a method of fabricating the image sensor may be provided.

Although exemplary embodiments have been described, the present disclosure should not be limited to these embodiments. It will be understood by one of ordinary skill in the art that variations in form and detail may be made therein without departing from the spirit and scope of the attached claims. It will also be understood by one of ordinary skill in the art that one or more features of an embodiment of this disclosure may be variously combined with one or more features of another embodiment of this disclosure.

What is claimed is:

1. An image sensor, comprising:
a plurality of light-receiving regions formed on a first surface of a substrate and disposed adjacent to each other, the plurality of light-receiving regions including a first light-receiving region and a second light-receiving region disposed adjacent to the first light-receiving region;
a photodiode isolation pattern formed on the first surface of the substrate, the photodiode isolation pattern configured to electrically isolate the first light-receiving region from the second light-receiving region; and
a back-side structure disposed on a second surface of the substrate opposite from the first surface, the back-side structure comprising a grid air region and a light-scattering air region,
wherein the grid air region has a grid shape, and
wherein the light-scattering air region overlaps with the first light-receiving region.

2. The image sensor of claim 1, wherein the grid air region overlaps with the photodiode isolation pattern.

3. The image sensor of claim 1, wherein the light-scattering air region is enclosed by the grid air region.

4. The image sensor of claim 1, wherein the back-side structure further comprises a micro lens configured to overlap with at least one of the plurality of light-receiving regions, and wherein the micro lens has a convex shape.

5. The image sensor of claim 1, wherein the back-side structure further comprises:
a light-transparent pattern comprising the grid air region and the light-scattering air region; and
a micro lens layer disposed on the light-transparent pattern.

6. The image sensor of claim 5, wherein the micro lens layer forms a top of the grid air region and a top of the light-scattering air region.

7. The image sensor of claim 5, wherein the light-transparent pattern comprises a coloring agent.

8. The image sensor of claim 5, wherein a refractive index of the light-transparent pattern is higher than a refractive index of the grid air region or a refractive index of the light-scattering air region.

9. The image sensor of claim 5, wherein the photodiode isolation pattern comprises:
an isolation insulating pattern in contact with the substrate; and
an isolation conductive pattern spaced apart from the substrate with the isolation insulating pattern interposed therebetween,
wherein a density of the light-transparent pattern is lower than a density of the isolation insulating pattern.

10. The image sensor of claim 1, wherein the light-scattering air region has one of a cross shape, a star shape, a polygonal shape, or a closed curve shape, when viewed in a plan view.

11. An image sensor, comprising:
a plurality of light-receiving regions formed on a substrate; and
a back-side structure disposed on a rear surface of the substrate, the back-side structure comprising a grid air region and a light-scattering air region,
wherein the grid air region has a grid shape,
wherein the light-scattering air region overlaps with a light-receiving region of the plurality of light-receiving regions, and
wherein a refractive index of a material constituting the back-side structure is higher than a refractive index of the grid air region or the light-scattering air region.

12. The image sensor of claim 11, further comprising a photodiode isolation pattern disposed in the substrate to electrically isolate the plurality of light-receiving regions, wherein the grid air region overlaps with the photodiode isolation pattern.

13. The image sensor of claim 11, wherein the light-scattering air region is enclosed by the grid air region.

14. The image sensor of claim 11, wherein the back-side structure comprises:
a light-transparent pattern comprising the grid air region and the light-scattering air region; and
a micro lens layer disposed on the light-transparent pattern.

15. The image sensor of claim 14, wherein the light-transparent pattern comprises a coloring agent.

16. The image sensor of claim 14, wherein the photodiode isolation pattern comprises:
an isolation insulating pattern in contact with the substrate; and
an isolation conductive pattern spaced apart from the substrate with the isolation insulating pattern interposed therebetween,
wherein a density of the light-transparent pattern is lower than a density of the isolation insulating pattern.

17. An image sensor, comprising:
a plurality of light-receiving regions formed on a first surface of a substrate and including a first light-receiving region and a second light-receiving region disposed adjacent to the first light-receiving region;
a photodiode isolation pattern configured to electrically isolate the first light-receiving region from the second light-receiving region;
a photodiode disposed in each of the plurality of light-receiving regions of the substrate;
a transfer transistor disposed on the first surface of the substrate;
a floating diffusion region disposed on a portion of the substrate adjacent to the transfer transistor;
a fixed charge layer covering a second surface of the substrate opposite from the first surface; and
a back-side structure formed on the fixed charge layer,
wherein the back-side structure comprises:
a light-transparent pattern comprising a grid air region and a light-scattering air region; and
a micro lens layer disposed on the light-transparent pattern,
wherein the grid air region has a grid shape,
wherein the light-scattering air region overlaps with the first light-receiving region, and
wherein a refractive index of the light-transparent pattern is higher than a refractive index of the grid air region or the light-scattering air region.

18. The image sensor of claim 17, wherein the grid air region overlaps with the photodiode isolation pattern.

19. The image sensor of claim 17, wherein the light-scattering air region is enclosed by the grid air region.

20. The image sensor of claim 17, wherein the light-transparent pattern comprises a coloring agent.
